(19) United States
(12) Patent Application Publication
(10) Pub. No.: US 2012/0228744 A1
(43) Pub. Date: Sep. 13, 2012

(54) WAFER AND METHOD OF MANUFACTURING PACKAGE PRODUCT

(76) Inventor: Yasuo Kawada, Chiba-shi (JP)

(21) Appl. No.: 13/411,969

(22) Filed: Mar. 5, 2012

(30) Foreign Application Priority Data
Mar. 7, 2011 (JP) 2011-049454

(51) Int. Cl. H01L 27/06; H01L 21/78

(52) U.S. Cl. 257/620; 438/113; 257/E27.011; 257/E21.599

(57) ABSTRACT

To provide a wafer in which out-gas emitted between wafers during bonding of the wafers can be easily discharged to the outside and the bonded wafers can be favorably cut to improve the yields, and a method of manufacturing a package product using the wafer. A groove portion is formed in a wafer for lid substrate along a plurality of imaginary straight lines passing through a center in a diameter direction of the wafer for lid substrate and extending in the diameter direction. The groove portion is divided into a plurality of groove portions in the diameter direction placed such that the groove portions are not in contact with each other.

### RELATED APPLICATIONS

This application claims priority under 35 U.S.C. §119 to Japanese Patent Application No. 2011-049454 filed on Mar. 7, 2011, the entire content of which is hereby incorporated by reference.

### BACKGROUND OF THE INVENTION

1. Field of the Invention

The present invention relates to a wafer and a method of manufacturing a package product.

2. Description of the Related Art

In recent years, a package product has been widely used which includes a base substrate and a lid substrate placed one on another, anodic-bonded together, and having cavities between them, and also includes operating strips each mounted at a portion located within the cavity in the base substrate. Known examples of the package product of this type include a piezoelectric oscillator mounted on a cellular phone or a portable information terminal and using crystal or the like as a time source, a timing source for a control signal or the like, or a reference signal.

This package product is formed in the following manner.

First, a wafer for base substrate and a wafer for lid substrate are set on an anodic bonding device placed within a vacuum chamber and are placed one on another with a bonding film for anodic bonding made of a conductive material interposed between them.

A bonding face of the wafer for lid substrate has a number of recess portions which can serve as the cavities when the wafer is placed on the wafer for base substrate. A number of operating strips are mounted on a bonding face of the wafer for base substrate in association with the recess portions, and the bonding film is formed on the bonding face except for the portions where the operating strips are mounted. The wafer for lid substrate is set on an electrode plate of the anodic bonding device.

Next, while the wafer for lid substrate is heated to activate ions inside, a voltage is applied between the bonding film and the electrode plate to pass an electric current through the wafer for lid substrate to cause an electrochemical reaction in the interface between the bonding film and the bonding face of the wafer for lid substrate. This anodic-bonds them to form a wafer bonded unit.

Then, the wafer bonded unit is cut at a predetermined position (between the respective cavities) to form a number of package products.

During the anodic bonding described above, the wafers tend to be bonded earlier in outer peripheral portions than in central portions of the product region where the recess portions (cavities) or the operating strips are placed. Since out-gas (for example, oxygen gas) emitted between the wafers stays between the central portions, the resulting package products obtained from those central portions have a low degree of vacuum within the cavities. Thus, some package products may not have desired performance, may have a lower bonding strength in the central portions than the bonding strength in the outer peripheral portions due to distortion of the central portions, or may not be bonded between the central portions in a worse case scenario.

To address this, for example Patent Document 1 (WO 2010/061470) has disclosed a technology as shown in FIG. 18 in which a plurality of groove portions 122 are formed at equal intervals around the center of a wafer for lid substrate 150 to extend from the center toward the outer side in a radial direction to discharge out-gas emitted between wafers during bonding from between the wafers to the outside.

### SUMMARY OF THE INVENTION

In the structure of Patent Document 1 described above, however, the plurality of groove portions 122 are formed to intersect, so that cutting of the wafer bonded unit between cavities 103a needs to be performed across the groove portion 122. As shown in FIG. 19, the cutting performed across the groove portion 122 may not be performed along a desired cutting line Z but may cause cracks running from the groove portion 122 toward directions X and Y in which strength is lower.

In this case, if the crack running in the package product reduces the strength of the package product or reaches the cavity 103a, the cavity 103a communicates with the outside and the hermetic sealing of the cavity 103a cannot be maintained. This may result in reduced yields.

The present invention has been made in view of such circumstances, and it is an object thereof to provide a wafer in which out-gas emitted between wafers during bonding of the wafers can be easily discharged to the outside and the bonded wafers can be favorably cut to improve the yields, and a method of manufacturing a package product using the wafer.

The present invention provides a wafer for forming a number of package products in which wafers are placed one on another and anodic-bonded to have a cavity between the wafers for housing an operating piece, wherein a groove portion is formed in a wafer body along a plurality of straight lines passing through a center in a diameter direction of the wafer body and extending in the diameter direction, and the groove portion is divided into a plurality of groove portions in the diameter direction placed such that the groove portions are not in contact with each other.

According to the present invention, the groove portion formed in the wafer can guide out-gas emitted between the wafers during the bonding to the groove portion. As a result, the wafers can be bonded with a small amount of out-gas remaining in the cavity, so that the package product can be manufactured at a high degree of vacuum in the cavity.

Particularly, in cutting the bonded wafers into package products, both sides of the groove portion are previously cut along the straight lines and then the wafers are cut between the cavities, thereby eliminating the need to perform the cutting across the groove portion. This can cut the wafer bonded unit along a desired cutting line.

This can prevent the cutting from deviating from the desired cutting line to cause cracks, so that it is possible to increase the strength of the package product and to prevent defective items in which the cavity communicates with the outside. Thus, the yields can be improved.

In the wafer according to one aspect of the present invention, the plurality of straight lines are formed such that two straight lines are orthogonal to each other and each of the straight lines is formed along one side of the cavity.

According to this aspect, the groove portion can be formed while suppressing an increase in space between the adjacent cavities. This can maintain the yields of the group of package products which can be formed from one wafer. As a result, even when the groove portion is formed, the number of the package products taken from one wafer can be ensured.

In the wafer according to one aspect of the present invention, the two straight lines orthogonal to each other are formed to intersect at the center in the diameter direction of the wafer body, and a non-forming region of the groove portion is set at the center in the diameter direction of the wafer body.

According to this aspect, the groove portion can be cut out with the small number of cutting steps to provide the wafer in which package products can be manufactured efficiently. Since the sizes of the cut wafer body portions can be uniform, the operation of the next step can be facilitated.

The present invention also provides a method of manufacturing a package product for forming a number of package products in which two wafers are placed one on another and anodic-bonded to have a cavity between the wafers for housing an operating piece, including a wafer forming step of forming a wafer according to the present invention of the two wafers, an anodic-bonding step of anodic-bonding the wafer formed at the wafer forming step and another wafer placed one on another, and a cutting step of cutting the two wafers anodic-bonded at the anodic-bonding step, wherein, at the cutting step, the wafer is cut along the straight line on both sides of the groove portion formed in the wafer and over the entire diameter direction of the wafer such that the cutting is performed through a portion where the groove portion is not formed.

According to the present invention, the groove portion formed in the wafer can guide out-gas emitted between the wafers during the bonding to the groove portion. As a result, the wafers can be bonded with a small amount of out-gas remaining in the cavity, so that the package product can be manufactured at a high degree of vacuum in the cavity.

Particularly, in cutting the bonded wafers into package products, both sides of the groove portion are previously cut along the straight lines and then the wafers are cut between the cavities, thereby eliminating the need to perform the cutting across the groove portion. This can cut the wafer bonded unit along a desired cutting line.

This can prevent the cutting from deviating from the desired cutting line to cause cracks, so that it is possible to increase the strength of the package product and to prevent defective items in which the cavity communicates with the outside. Thus, the yields can be improved.

The wafer and the method of manufacturing a package product according to the present invention can improve yields since the out-gas emitted between the wafers during the wafer bonding can be easily discharged to the outside and the bonded wafers can be favorably cut.

### BRIEF DESCRIPTION OF THE DRAWINGS

FIG. 1 shows an embodiment of the present invention and is an external perspective view of a piezoelectric oscillator.

FIG. 2 is a diagram showing the internal structure of the piezoelectric oscillator shown in FIG. 1 and shows a piezoelectric oscillating piece from above with a lid substrate removed.

FIG. 3 is a section view of the piezoelectric oscillator taken along line A-A shown in FIG. 2.

FIG. 4 is a section view of the piezoelectric oscillator taken along line B-B shown in FIG. 2.

FIG. 5 is an exploded perspective view of the piezoelectric oscillator shown in FIG. 1.

FIG. 6 is a plan view of the piezoelectric oscillating piece forming part of the piezoelectric oscillator shown in FIG. 1.

FIG. 7 is a bottom view of the piezoelectric oscillating piece shown in FIG. 5.

FIG. 8 is a section view of the piezoelectric oscillating piece taken along line C-C shown in FIG. 6.

FIG. 9 is a flow chart showing the flow in manufacturing the piezoelectric oscillator shown in FIG. 1.

FIG. 10 is a diagram showing a step in manufacturing the piezoelectric oscillator with the flow chart shown in FIG. 9, and shows an embodiment in which recess portions and groove portions are formed in a wafer for lid substrate serving as a source of a lid substrate.

FIG. 11 is a diagram showing a step in manufacturing the piezoelectric oscillator with the flow chart shown in FIG. 9, and is a plan view of a wafer for base substrate serving as a source of a base substrate.

FIG. 12 is a diagram showing a step in manufacturing the piezoelectric oscillator with the flow chart shown in FIG. 9, and shows a pair of thorough holes formed in the wafer for base substrate.

FIG. 13 is a diagram showing a through electrode formed in the pair of through holes as well as a bonding film and a routing electrode patterned on an upper face of the wafer for base substrate, after the state shown in FIG. 12.

FIG. 14 is a schematic diagram showing the wafer for base substrate and the wafer for lid substrate set on an anodic bonding device.

FIG. 15 is a diagram showing a step in manufacturing the piezoelectric oscillator with the flow chart shown in FIG. 9, and is an exploded perspective view of a wafer bonded unit in which the wafer for base substrate and the wafer for lid substrate are anodic-bonded together with the piezoelectric oscillating piece housed in the cavity.

FIGS. 16A and 16B are diagrams showing a step in manufacturing the piezoelectric oscillator with the flow chart shown in FIG. 9, and show a cutting step.

FIG. 17 is a diagram showing another embodiment of the present invention.

FIG. 18 is a plan view showing a wafer for lid substrate in the related art.

FIG. 19 is an explanatory drawing for explaining a method of cutting a wafer bonded unit in the related art.

### DETAILED DESCRIPTION OF THE PREFERRED EMBODIMENT

Next, an embodiment of the present invention will be described with reference to the drawings.

The present embodiment will be described in conjunction with an example of a piezoelectric oscillator as a package product including a base substrate and a lid substrate placed one on another, anodic-bonded together, and having cavities between them, and also including operating strips each mounted at a portion located within the cavity in the base substrate.

### (Piezoelectric Oscillator)

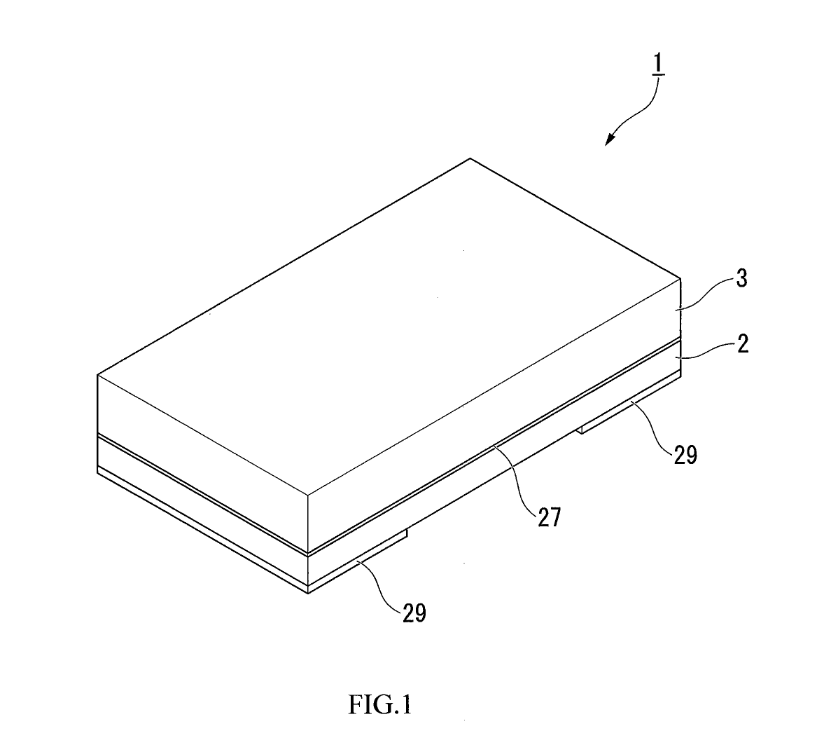

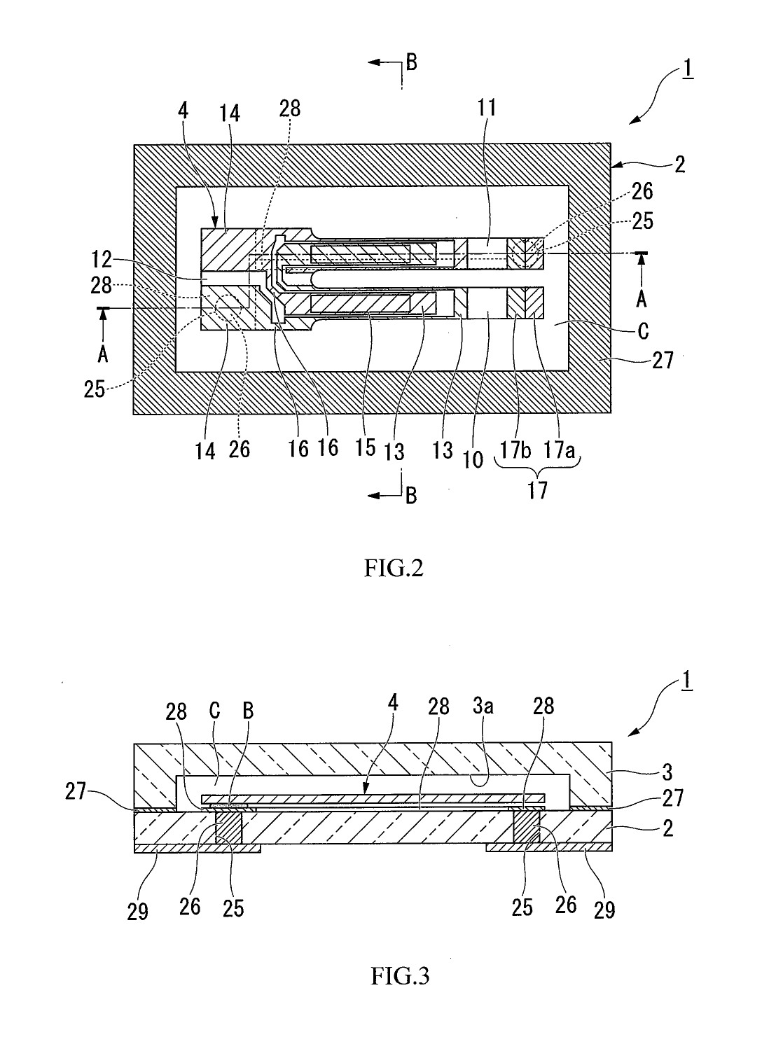

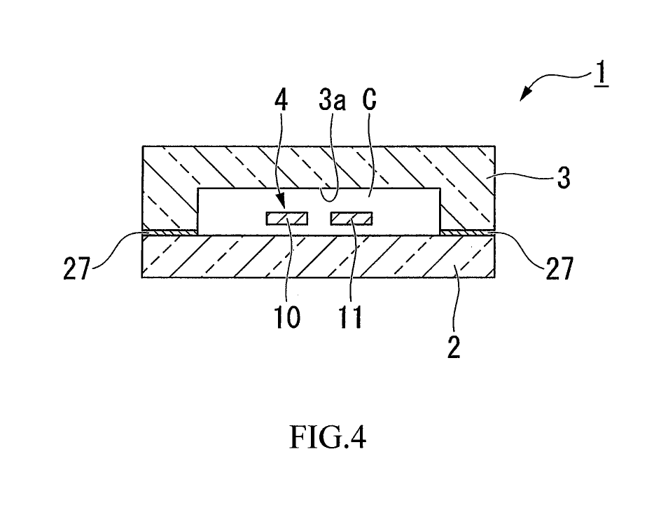

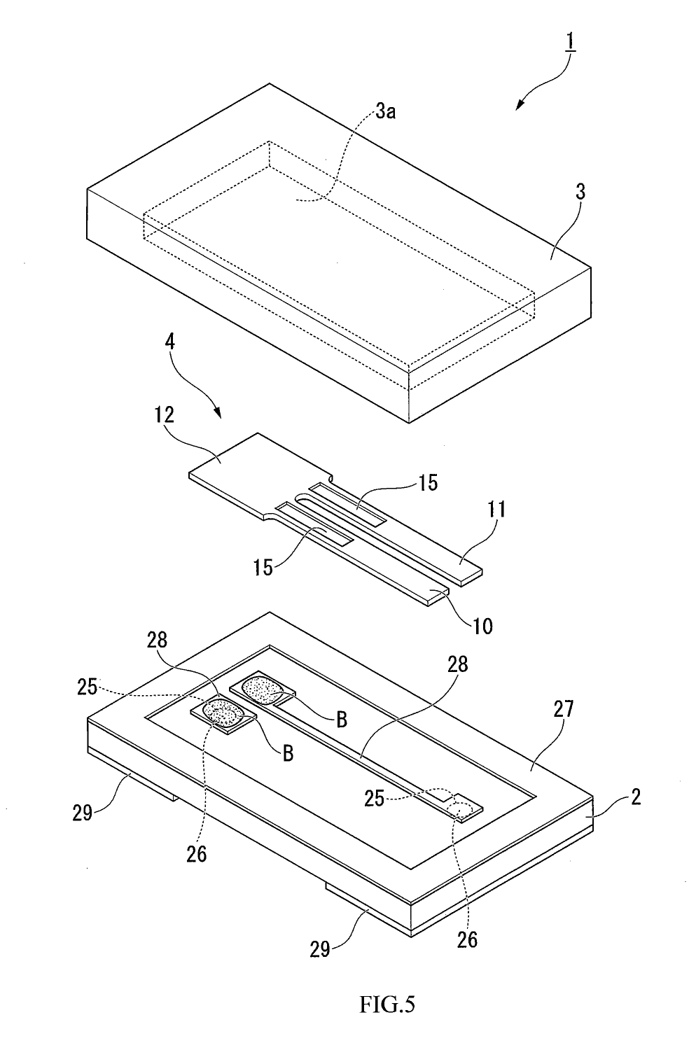

FIG. 1 is an external perspective view of a piezoelectric oscillator in the present embodiment. FIG. 2 is a diagram showing the internal structure of the piezoelectric oscillator and shows a piezoelectric oscillating piece from above with a lid substrate removed. FIG. 3 is a section view of the piezoelectric oscillator taken along line A-A shown in FIG. 2. FIG. 4 is a section view of the piezoelectric oscillator taken along line B-B shown in FIG. 2. FIG. 5 is an exploded perspective view of the piezoelectric oscillator.

As shown from FIG. 1 to FIG. 5, the piezoelectric oscillator 1 is formed in a box shape including two layers of a base substrate 2 and a lid substrate 3, and is of a surface-mounting type having a piezoelectric oscillating piece (operating piece) 4 housed in an inside cavity C. In FIG. 5, an exciting electrode 13, a lead electrode 16, a mount electrode 14, and a weight metal film 17, later described, are omitted for clarity of the drawing.

### (Piezoelectric Oscillating Piece)

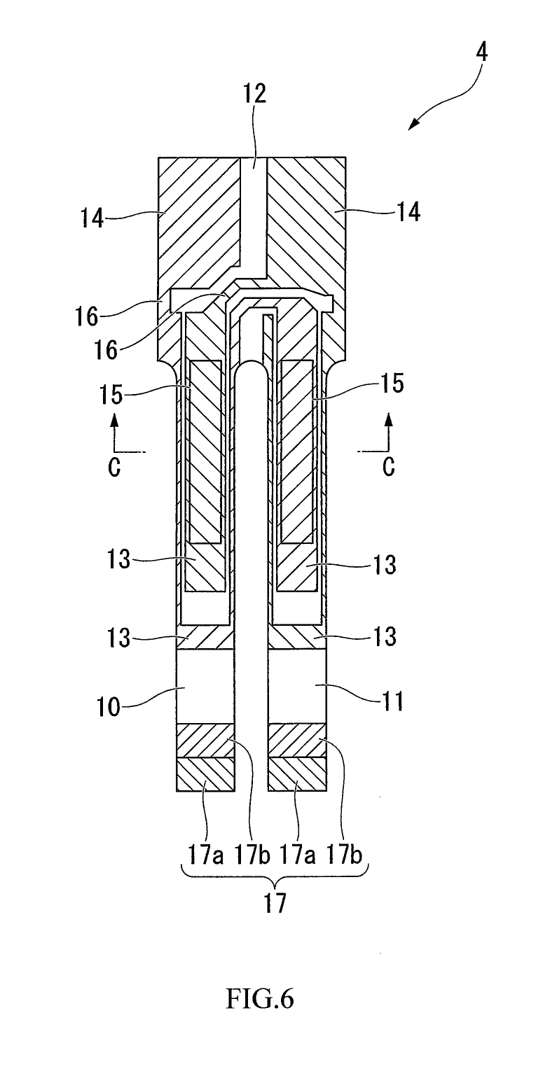

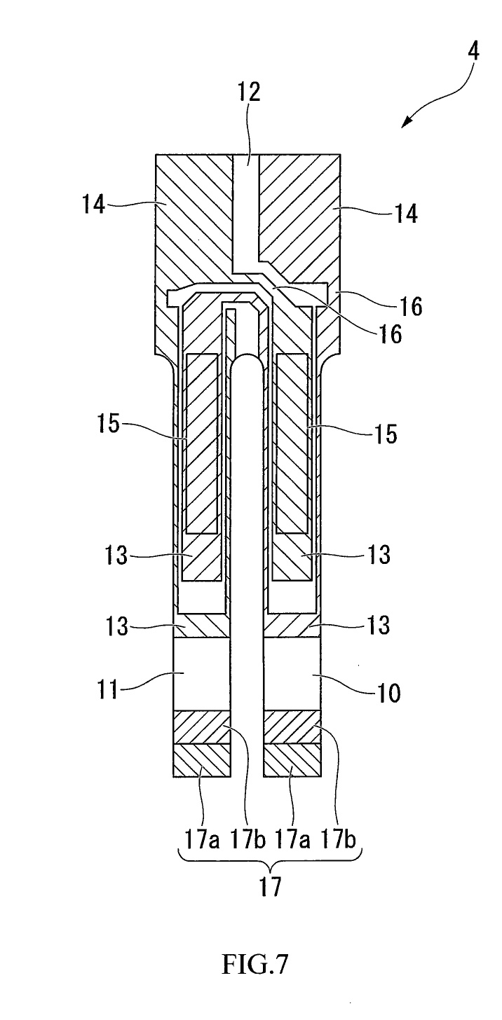

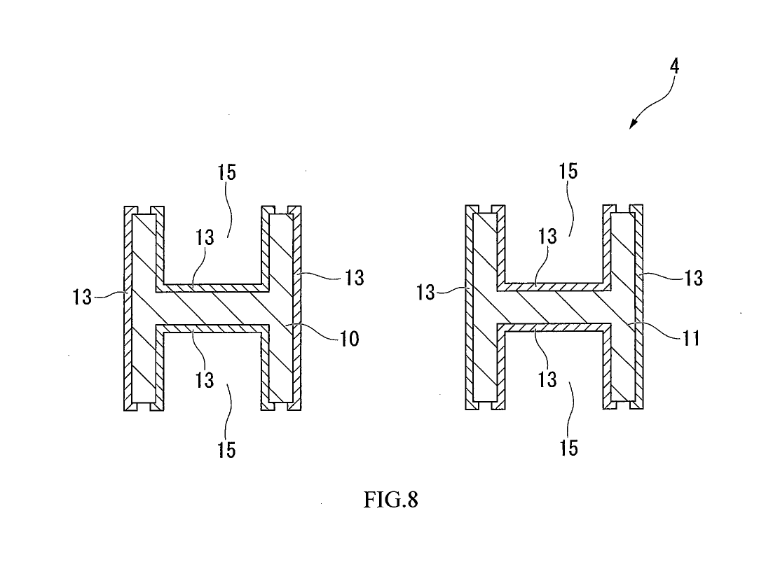

FIG. 6 is a plan view of the piezoelectric oscillating piece forming part of the piezoelectric oscillator. FIG. 7 is a bottom view of the piezoelectric oscillating piece. FIG. 8 is a section view taken along line C-C in FIG. 6.

As shown from FIG. 6 to FIG. 8, the piezoelectric oscillating piece 4 is a tuning fork-type oscillating piece made of a piezoelectric material such as crystal, lithium tantalate, and a lithium niobate, and oscillates in response to application of a predetermined voltage.

The piezoelectric oscillating piece 4 has a pair of oscillating arm portions 10 and 11 placed in parallel, a base portion 12 integrally fixing the pair of oscillating arm portions 10 and 11 at their base ends, the exciting electrode 13 formed on each of outer faces of the pair of oscillating arm portions 10 and 11 to oscillate the pair of oscillating arm portions 10 and 11, and the mount electrode 14 electrically connected to the exciting electrode 13. The piezoelectric oscillating piece 4 of the present embodiment has a groove portion 15 formed on each of main faces of the pair of oscillating arm portions 10 and 11 along the longitudinal direction of the oscillating arm portions 10 and 11. The groove portion 15 is formed from the base end of the oscillating arm portions 10 and 11 to near a generally intermediate portion.

The exciting electrode 13 is an electrode for oscillating the pair of oscillating arm portions 10 and 11 at a predetermined resonance frequency in directions in which they are brought closer to or away from each other, and is formed through patterning on each of the outer faces of the pair of oscillating arm portions 10 and 11 such that the exciting electrodes 13 are electrically isolated from each other. Specifically, as shown in FIG. 8, one of the exciting electrodes 13 is formed mainly on the groove portion 15 of one oscillating arm portion 10 and on both side faces of the other oscillating arm portion 11, and the other of the exciting electrodes 13 is formed mainly on both side faces of the one oscillating arm portion 10 and on the groove portion 15 of the other oscillating arm portion 11.

As shown in FIG. 6 and FIG. 7, the exciting electrode 13 is electrically connected to the mount electrode 14 through the lead electrode 16 on each of the main faces of the base portions 12. A voltage is applied to the piezoelectric oscillating piece 4 through the mount electrode 14. Each of the exciting electrode 13, the mount electrode 14, and the lead electrode 16 described above is formed of a conductive film made of chromium (Ch), nickel (Ni), aluminum (Al), titanium (Ti) or the like, for example.

The weight metal film 17 is deposited on each of tips of the pair of oscillating arm portions 10 and 11 for adjusting the oscillating state thereof to oscillate within a range of predetermined frequencies (frequency adjustment). The weight metal film 17 is divided into a rough-adjustment film 17a used in roughly adjusting the frequency and a fine-adjustment film 17b used in fine adjustment. The frequency adjustment is performed by using the rough-adjustment film 17a and the fine-adjustment film 17b to allow the frequency of the pair of oscillating arm portions 10 and 11 to fall within the range of nominal frequencies of the device.

As shown in FIG. 2, FIG. 3, and FIG. 5, the piezoelectric oscillating piece 4 formed in this manner is bump-bonded to an upper face of the base substrate 2 with bumps B made of gold or the like. More specifically, the pair of mount electrodes 14 are bump-bonded onto and in contact with the two bumps B formed on routing electrodes 28, later described. This causes the piezoelectric oscillating piece 4 to be supported such that it is separate from the upper face of the base substrate 2 and that the mount electrode 14 and the routing electrode 28 are electrically connected to each other.

The lid substrate 3 is a transparent insulating substrate made of a glass material, for example soda-lime glass, and is formed in a plate shape as shown in FIG. 1, FIG. 3, FIG. 4, and FIG. 5. A recess portion 3a having a rectangular shape in plan view for housing the piezoelectric oscillating piece 4 is formed in a bonding face of the lid substrate 3 to which the base substrate 2 is bonded. This recess portion 3a serves as a cavity C for housing the piezoelectric oscillating piece 4 when both substrates 2 and 3 are placed one on another. The recess portion 3a is closed by the base substrate 2 through the anodic bonding of the lid substrate 2 and the base substrate 3.

The base substrate 2 is a transparent insulating substrate made of a glass material, for example soda-lime glass, similarly to the lid substrate 3. As shown from FIG. 1 to FIG. 5, the base substrate 2 is formed in a plate shape with a size which can be placed on the lid substrate 3. The base substrate 2 has a pair of through holes 25 passing through the base substrate 2. The pair of through holes 25 is formed to be placed within the cavity C. More specifically, one through hole 25 is located closer to the base portion 12 of the mounted piezoelectric oscillating piece 4, and the other through hole 25 is located closer to the tips of the oscillating arm portions 10 and 11.

While the shown example is described with an example in which the through hole 25 has an equal internal diameter over the entire region in a plate thickness direction of the base substrate 2, the present invention is not limited thereto, and the through hole 25 may have a tapered internal diameter gradually reduced or increased along the plate thickness direction, for example. It is required only that the through hole 25 should pass through the base substrate 2.

A through electrode 26 is embedded in each of the pair of through holes 25. The through electrode 26 completely fills the through hole 25 to hold the cavity C hermetically sealed and electrically conducts an external electrode 29, later described, to the routing electrode 28. A bonding face of the base substrate 2 to which the lid substrate 3 is bonded has a bonding film 27 for anodic bonding and the pair of routing electrodes 28 patterned thereon with a conductive material such as aluminum. The bonding film 27 is placed to surround the recess portion 3a on the bonding face to the lid substrate 3 substantially over the entire region of the portion where the recess portion 3a is not formed.

The pair of routing electrodes 28 are patterned to electrically connect one through electrode 26 of the pair of through electrodes 26 with one mount electrode 14 of the piezoelectric oscillating piece 4 and to electrically connect the other through electrode 26 with the other mount electrode 14 of the piezoelectric oscillating piece 4. More specifically, as shown in FIG. 2 and FIG. 5, one routing electrode 28 is formed immediately above one through electrode 26 to be located immediately below the base portion 12 of the piezoelectric oscillating piece 4. The other routing electrode 28 is routed from the position adjacent to the one routing electrode 28 toward the tip along the oscillating arm portion 11 and then is located immediately above the other through electrode 26.

The bumps B are formed on the pair of routing electrodes 28 and are used to mount the piezoelectric oscillating piece 4. This causes one mount electrode 14 of the piezoelectric oscillating piece 4 to conduct electrically to one through electrode 26 through one routing electrode 28 and causes the other mount electrode 14 to conduct electrically to the other through electrode 26 through the other routing electrode 28.

As shown in FIG. 1, FIG. 3, and FIG. 5, the external electrode 29 is formed on the face of the base substrate 2 opposite to the bonding face for electrical connection to each of the pair of through electrodes 26. Specifically, one external electrode 29 is electrically connected to one exciting electrode 13 of the piezoelectric oscillating piece 4 through one through electrode 26 and one routing electrode 28, and the other external electrode 29 is electrically connected to the other exciting electrode 13 of the piezoelectric oscillating piece 4 through the other through electrode 26 and the other routing electrode 28.

For operating the piezoelectric oscillator 1 formed in this manner, a predetermined driving voltage is applied to the external electrode 29 formed on the base substrate 2. This can pass an electric current through the exciting electrode 13 of the piezoelectric oscillating piece 4 to oscillate the pair of the oscillating arm portions 10 and 11 at a predetermined frequency in directions in which they are brought closer to or away from each other. The oscillation of the pair of the oscillating arm portions 10 and 11 can be used as a time source, a timing source for a control signal, a reference signal source or the like.

### (Method of Manufacturing Piezoelectric Oscillator)

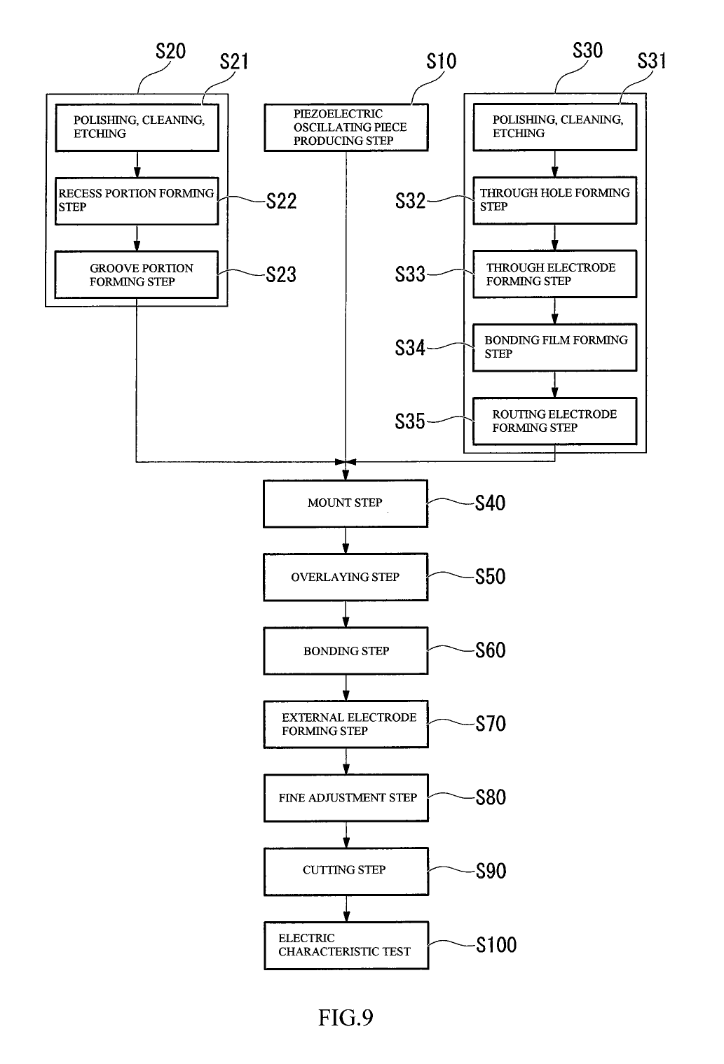

Next, description will be made of a method of manufacturing a number of piezoelectric oscillators 1 as described above at a time by using a wafer for base substrate (another wafer) 40 and a wafer for lid substrate (wafer body) 50 with reference to a flow chart shown in FIG. 9.

First, the piezoelectric oscillating piece 4 shown from FIG. 6 to FIG. 8 is produced by performing a piezoelectric oscillating piece producing step (S 10).

Specifically, a crystal lambert ore is first sliced at a predetermined angle into a wafer having a certain thickness. After the wafer is subjected to lapping and rough processing, the processing altered layer is removed through etching, and mirror polishing is performed such as polishing to provide the wafer having a predetermined thickness. After the wafer is subjected to proper treatment such as cleaning, the wafer is patterned into the outer shape of the piezoelectric oscillating piece 4 with a photolithography technology, and a metal film is deposited and patterned to form the exciting electrode 13, the lead electrode 16, the mount electrode 14, and the weight metal film 17. The plurality of piezoelectric oscillating pieces 4 can be produced as described above.

After the piezoelectric oscillating piece 4 is produced, rough adjustment is performed for the resonance frequency. This is performed by applying laser light to the rough adjustment film 17a of the weight metal film 17 to evaporate a portion thereof to change the weight. This allows the frequency to fall within a range slightly wider than the intended nominal frequencies. Fine adjustment of adjusting the resonance frequency more accurately to cause the frequency to fall within the range of nominal frequencies ultimately is performed after mounting. This is described later.

### (First Wafer Producing Step)

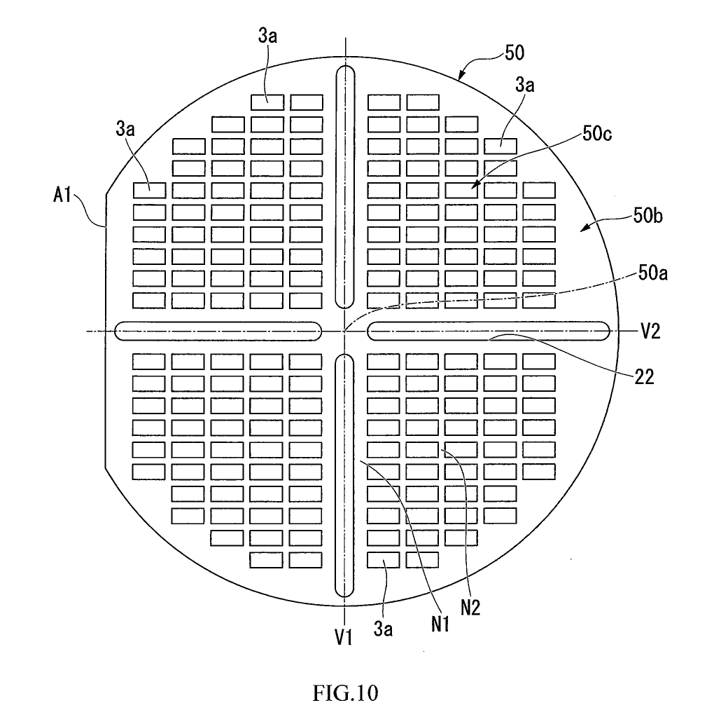

FIG. 10 is a diagram showing an embodiment in which recess portions and groove portions are formed in a wafer for lid substrate serving as a source of the lid substrate.

Next, a first wafer producing step (S20) is performed in which the wafer for lid substrate 50, which will provide the lid substrate 3, is produced to the state immediately before the anodic bonding is performed.

First, the soda-lime glass is polished to a predetermined thickness, cleaned, and then, subjected to etching or the like to remove a processing altered layer from an outermost face to provide the discoid wafer for lid substrate 50 as shown in FIG. 10 (S21). In the example shown, the wafer for lid substrate 50 is formed in a circular shape in plan view, and a reference mark portion A1 cut along a straight line (chord) connecting two points on the outer circumference is formed on the outer peripheral portion of the wafer 50.

Next, a recess portion forming step (S22) is performed in which a number of recess portions 3a for cavities C are formed with heat pressing, etching or the like, on a bonding face of the wafer for lid substrate 50 to which a wafer for base substrate 40 is to be bonded. Specifically, a number of recess portions 3a are formed at intervals along row and column directions in a portion (hereinafter referred to as a product region) 50c located on an inner side in a diameter direction than an outer peripheral portion 50b on the bonding face of the wafer for lid substrate 50. The recess portions 3a are formed in a region (recess portion forming region N2) except for a region (hereinafter referred to as a non-forming region N1) along two imaginary straight lines (straight lines) V1 and V2 set in the product region 50c. The imaginary straight lines V1 and V2 are set in the diameter direction of the entire wafer for lid substrate 50 and are orthogonal to each other at a central portion 50a in the diameter direction. In this case, the recess portion 3a is formed in a rectangular shape having a shorter-side direction extending in parallel with the imaginary straight line V1 and a longer-side direction extending in parallel with the imaginary straight line V2.

In the same step as the abovementioned recess portion forming step (S22), groove portions 22 recessed in a plate thickness direction are formed in the bonding face of the wafer for lid substrate 50 (S23). Specifically, the groove portions 22 are formed in the non-forming region N1 along the imaginary straight lines V1 and V2 from a position avoiding the central portion 50a in the diameter direction toward the outer side in the diameter direction. Thus, the groove portions 22 formed on the imaginary straight lines V1 and V2 are formed to be separate in the diameter direction and not to be in contact with each other. In this case, the central portion 50a in the diameter direction of the wafer for lid substrate 50 is set as a non-forming region of the groove portion 22.

Thus, on the bonding face of the wafer for lid substrate 50, the two groove portions 22 are formed on each of the imaginary straight lines V1 and V2 of the non-forming region N1 such that the central portion 50a in the diameter direction is sandwiched between the two groove portions 22. The groove portions 22 divide the product region 50c into the fan-shaped four recess portion forming regions N2. At the groove portion forming step (S23), the outer end of the groove portion 22 in a radial direction is preferably not opened from the outer circumference of the wafer 50 but is located on the inner side in the radial direction than the outer circumference of the wafer 50. This suppresses a reduction in strength of the wafer 50 due to the formation of the groove portions 22.

At this time, the first wafer producing step (S20) is finished.

The recess portions 3a and the groove portions 22 can be formed by screen printing other than the abovementioned heat pressing or etching. In this case, the recess portions 3a and the groove portions 22 can be formed simultaneously by screen-printing glass paste at necessary points (points other than the recess portions 3a and the groove portions 22) on the wafer for lid substrate 50. While the present embodiment is described with the case in which the recess portions 3a and the groove portions 22 are formed collectively at the same step, the recess portions 3a and the groove portions 22 may be formed in different steps. When the recess portions 3a and the groove portions 22 are formed in different steps, the order of the steps (S22 and S23) can be changed as appropriate.

### (Second Wafer Producing Step)

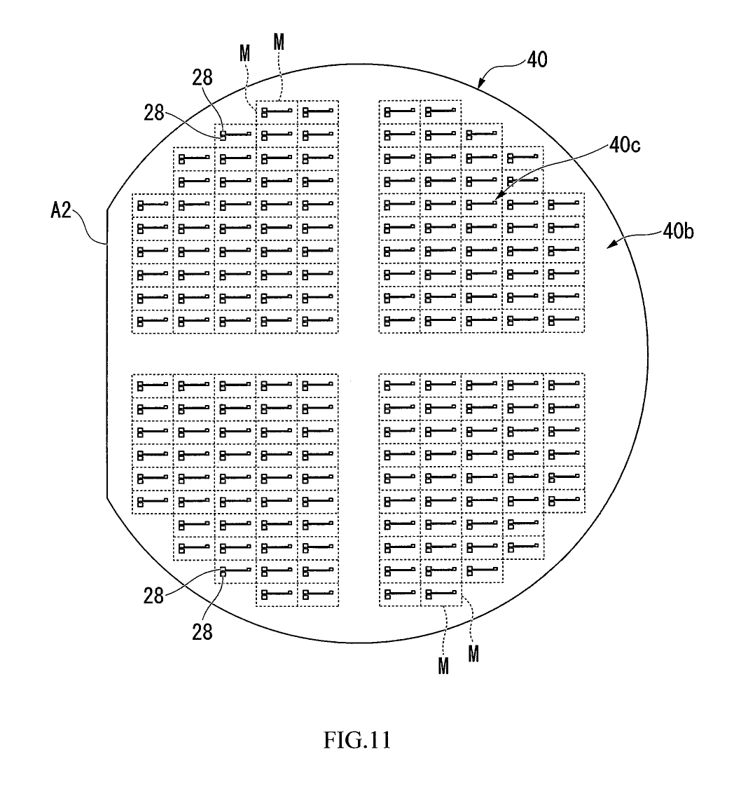

FIG. 11 is a plan view of a wafer for base substrate serving as a source of the base substrate.

Next, simultaneously with or after and before the abovementioned first wafer producing step (S20), a second wafer producing step (S30) is performed in which the wafer for base substrate 40, which will provide the base substrate 2, is produced to the state immediately before the anodic bonding is performed.

First, the soda-lime glass is polished to a predetermined thickness, cleaned, and then, subjected to etching or the like to remove a processing altered layer from an outermost face to provide the discoid wafer for base substrate 40 (S31). As shown in FIG. 11, the wafer for base substrate 40 is formed in a circular shape in plan view, and a reference mark portion A2 cut along a straight line (chord) connecting two points on the outer circumference is formed on the outer peripheral portion of the wafer 40.

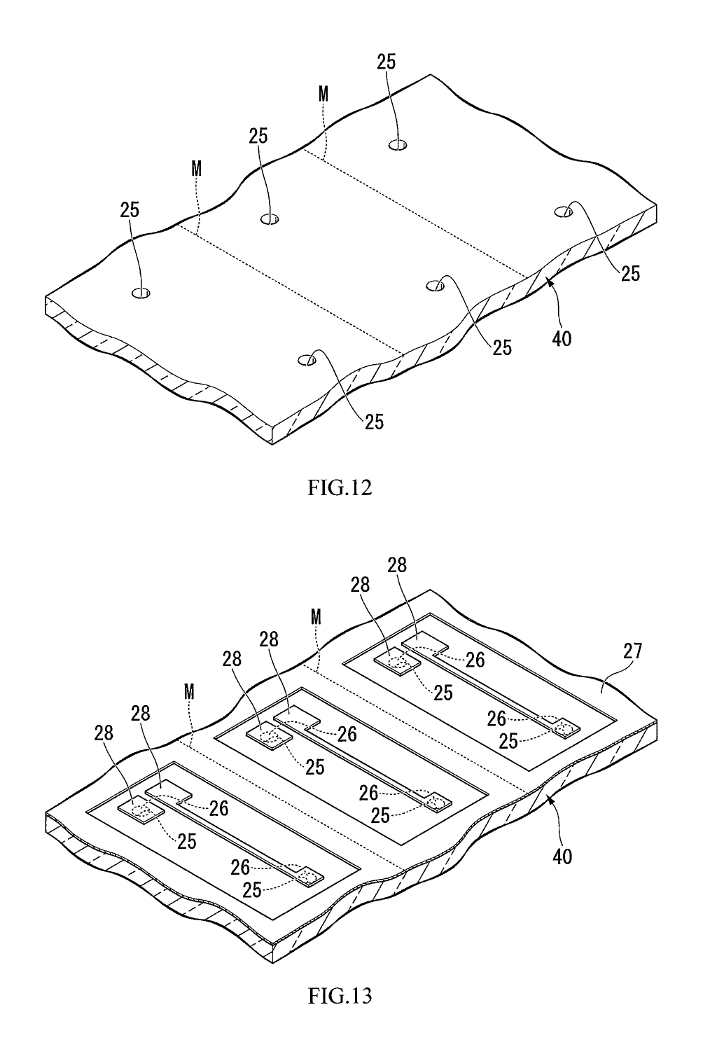

FIG. 12 is a diagram showing a pair of through holes formed in the wafer for base substrate.

Next, as shown in FIG. 12, a through hole forming step (S32) is performed in which a plurality of pairs of through holes 25 passing through the wafer for base substrate 40 are formed. Broken lines M shown in FIG. 12 indicate cutting lines for cutting at a cutting step (S 100) performed later. The through hole 25 is formed by a sandblast method or pressing with a jig, for example.

The pair of through holes 25 are formed at the positions placed within the recess portion 3a formed in the wafer for lid substrate 50 when both wafers 40 and 50 are later placed one on another, and at the positions in which one through hole 25 is placed closer to a base portion 12 of the piezoelectric oscillating piece 4 later mounted and the other through hole 25 is placed closer to the tip of an oscillating arm portion 11. In the example shown, the pairs of through holes 25 are formed in a portion (hereinafter referred to as a product region) 40c located on an inner side in a diameter direction than an outer peripheral portion 40b on the bonding face of the wafer for base substrate 40 to which the wafer lid substrate 50 is to be bonded. The plurality of pairs of through holes 25 are formed at regular intervals in one direction in the product region 40c and at intervals in the other direction orthogonal to the one direction. In the present embodiment, the pair of through holes 25 is not formed in the region of the product region 40c that faces the non-forming region N1 formed on the wafer for lid substrate 50. Thus, the pairs of through holes 25 are formed in the portion of the bonding face of the wafer for base substrate 40 except for the portion facing the non-forming region N1 and the outer peripheral portion 40b.

FIG. 13 is a diagram showing a through electrode formed in the pair of through holes as well as a bonding film and a routing electrode patterned on an upper face of the wafer for base substrate. In FIG. 13, the bonding film 27 is omitted.

Then, a through electrode forming step (S33) is performed in which the pair of through holes 25 is filled with a conductor, not shown, to form a pair of through electrodes 26. Next, a bonding film forming step (S34) is performed in which the conductive material is patterned on the bonding face of the wafer for base substrate 40 to form a bonding film 27 as shown in FIG. 12 and FIG. 13. A routing electrode forming step (S35) is performed in which a plurality of routing electrodes 28 electrically connected to the pair of through electrodes 26 are formed. These steps result in one through electrode 26 conducting electrically to one routing electrode 28 and the other through electrode 26 conducting electrically the other routing electrode 28.

At this time, the second wafer producing step (S30) is finished.

While FIG. 9 shows the order of the steps in which the routing electrode forming step (S35) is performed after the bonding film forming step (S34), the bonding film forming step (S34) may be performed after the routing electrode forming step (S35) in reverse order, or the steps may be performed simultaneously. The same operation and effect can be achieved in any step order. Thus, the step order may be changed as appropriate, as required.

Next, a mount step (S40) is performed in which the plurality of piezoelectric oscillating pieces 4 produced at the abovementioned piezoelectric oscillating piece producing step (S 10) are bump-bonded onto the surface of the wafer for base substrate 40 through the routing electrodes 28. First, a bump B made of gold or the like is formed on each of the pair of routing electrodes 28. After the base portion 12 of the piezoelectric oscillating piece 4 is placed on the bump B, the piezoelectric oscillating piece 4 is pushed against the bump B while the bump B is heated to a predetermined temperature. This causes the piezoelectric oscillating piece 4 to be mechanically supported on the bump B, and the mount electrode 14 is electrically connected to the routing electrode 28. Thus, the pair of exciting electrodes 13 of the piezoelectric oscillating piece 4 conduct electrically to the pair of through electrodes 26 at this point. Especially, since the piezoelectric oscillating piece 4 is bump-bonded, the piezoelectric oscillating piece 4 is supported to be separate from the bonding face of the wafer for base substrate 40.

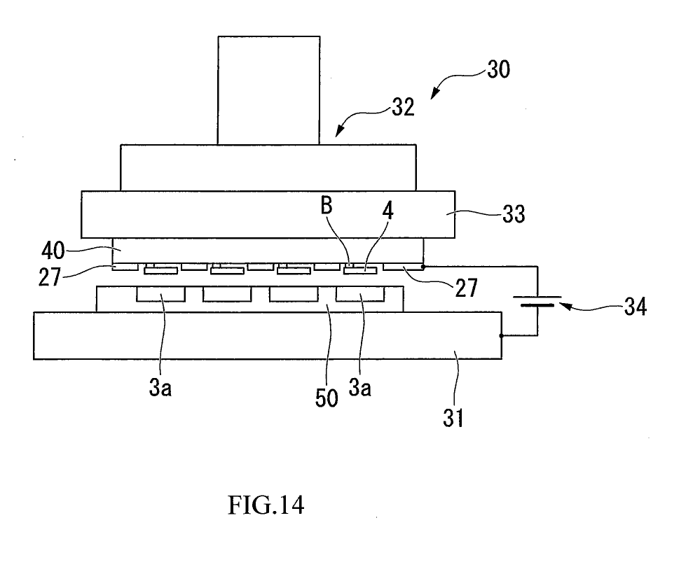

FIG. 14 is a schematic diagram showing the wafer for base substrate and the wafer for lid substrate set on the anodic bonding device.

Next, the wafer for base substrate 40 and the wafer for lid substrate 50 are set on the anodic bonding device 30.

As shown in FIG. 14, the anodic bonding device 30 includes a lower jig 31 made of a conductive material, an upper jig 33 supported by a pressurizing unit 32 to be movable toward and from the lower jig 31, and an energizing unit 34 for electrically connecting the bonding film 27 of the wafer for base substrate 40 set on the upper jig 33 to the lower jig 31, and is placed within a vacuum chamber, not shown.

The wafer for lid substrate 50 is set on the lower jig 31 with the recess portion 3a opened toward the upper jig 33, and the wafer for base substrate 40 is set on the upper jig 33 with the piezoelectric oscillating piece 4 opposed to the recess portion 3a of the wafer for lid substrate 50.

Then, the pressurizing unit 32 is driven to move the upper jig 33 toward the lower jig 31 to bring the piezoelectric oscillating piece 4 of the wafer for base substrate 40 into the recess portion 3a of the wafer for lid substrate 50, thereby performing an overlaying step (S50) for placing the wafers 40 and 50 one on another. This causes the piezoelectric oscillating piece 4 mounted on the wafer for base substrate 40 to be housed in the cavity C formed between the wafers 40 and 50.

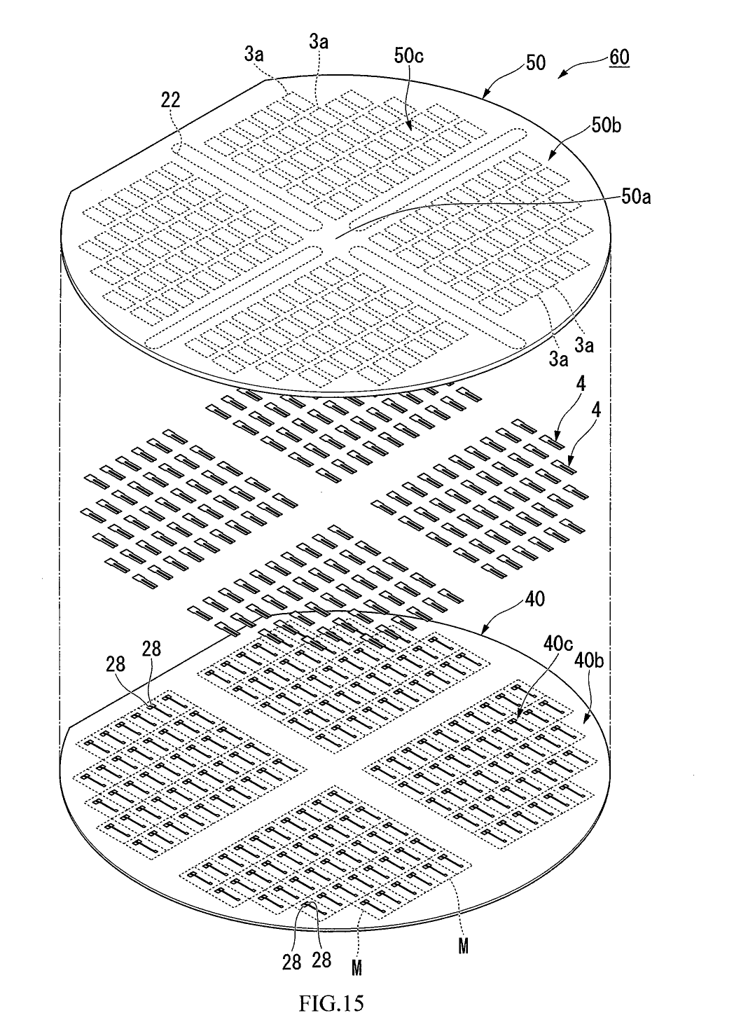

Next, a bonding step (S60) is performed in which a predetermined voltage is applied at a predetermined temperature to perform anodic bonding. Specifically, the energizing unit 34 applies the predetermined voltage between the bonding film 27 of the wafer for base substrate 40 and the lower jig 31. This causes an electrochemical reaction in the interface between the bonding film 27 and the bonding face of the wafer for lid substrate 50, so that they are brought into intimate contact with each other to achieve the anodic bonding. Thus, the piezoelectric oscillating piece 4 can be enclosed within the cavity C to provide a wafer bonded unit 60 as shown in FIG. 15 in which the wafer for base substrate 40 and the wafer for lid substrate 50 are bonded together.

FIG. 15 shows the exploded wafer bonded unit 60 for clarity of the drawing, and the bonding film 27 is omitted from the wafer for base substrate 40.

When the wafer bonded unit 60 is heated at the abovementioned bonding step (S60), out-gas is discharged from the bonding portion of the wafer bonded unit 60. The out-gas is partially discharged to the outside from the outer end portion of the wafer bonded unit 60 (the gap between the wafers 40 and 50). However, the remaining out-gas which is not discharged until the outer peripheral portions of the wafers 40 and 50 are bonded stays within the space surrounded by the groove portions 22 formed in the non-forming region N1 of the wafer for lid substrate 50 and the bonding face of the wafer for base substrate 40. Since the through hole 25 formed in the wafer for base substrate 40 is completely filled with the through electrode 26, the hermetical sealing of the cavity C is not compromised by the through hole 25 in performing the anodic bonding.

After the abovementioned anodic bonding is finished, an external electrode forming step (S70) is performed in which the conductive material is patterned on the surface of the wafer for base substrate 40 opposite to the bonding face to which the wafer for lid substrate 50 is bonded, so that a plurality of pairs of external electrodes 29 electrically connected to the pair of through electrodes 26 are formed. This step is provided to allow the piezoelectric oscillating piece 4 enclosed within the cavity C to be operated by using the external electrode 29.

Next, a fine adjustment step (S80) is performed in which the frequency of each piezoelectric oscillating piece 4 enclosed within the cavity C is fine adjusted to fall within a predetermined range in the state of the wafer bonded unit 60. More specifically, a voltage is applied to the external electrode 29 to oscillate the piezoelectric oscillating piece 4. While measuring the frequency, laser light is applied from the outside through the wafer for lid substrate 50 to evaporate the fine adjustment film 17b of the weight metal film 17. This can change the weight of the pair of the oscillating arm portions 10 and 11 on the tip side to perform the fine adjustment such that the frequency of the piezoelectric oscillating piece 4 falls within the predetermined range of nominal frequencies.

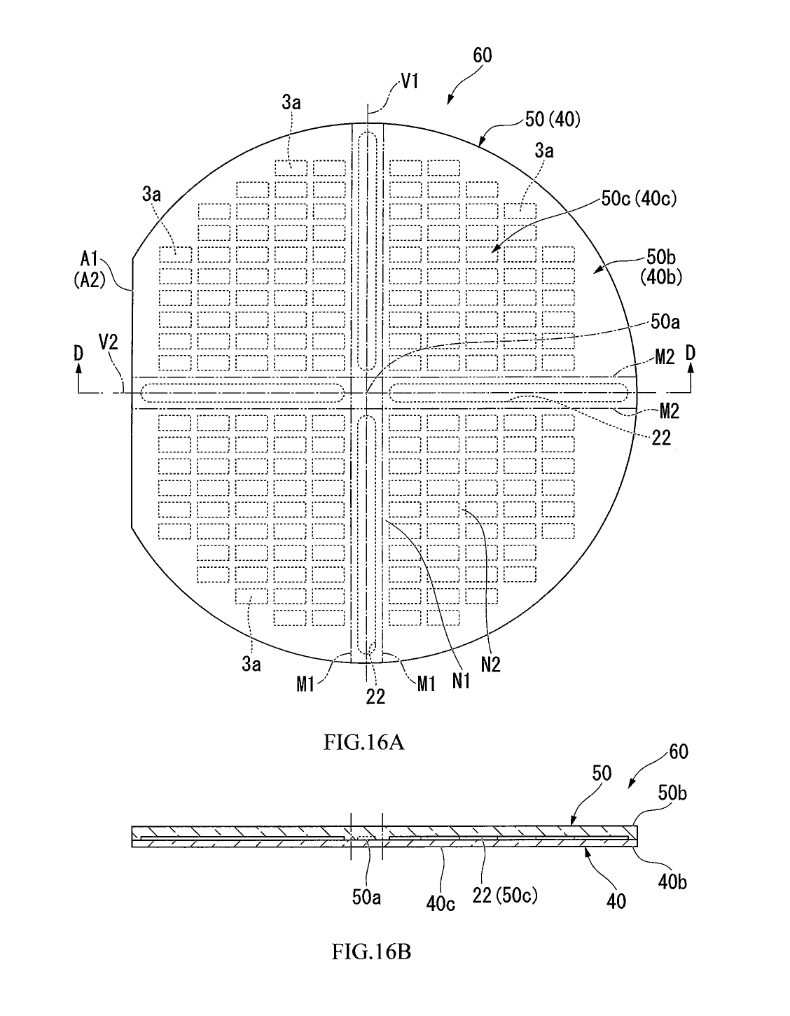

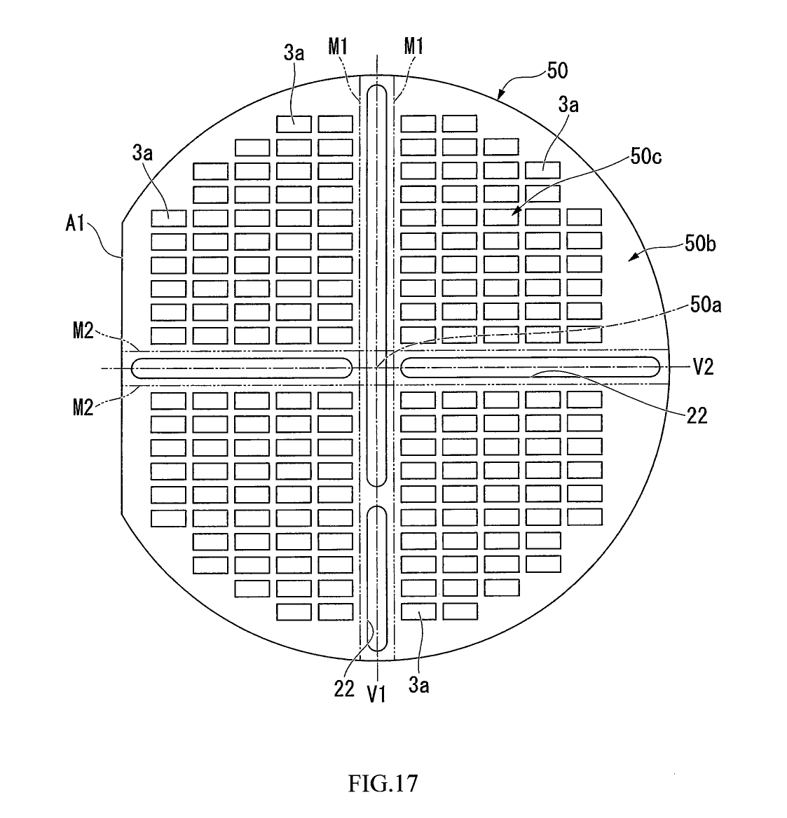

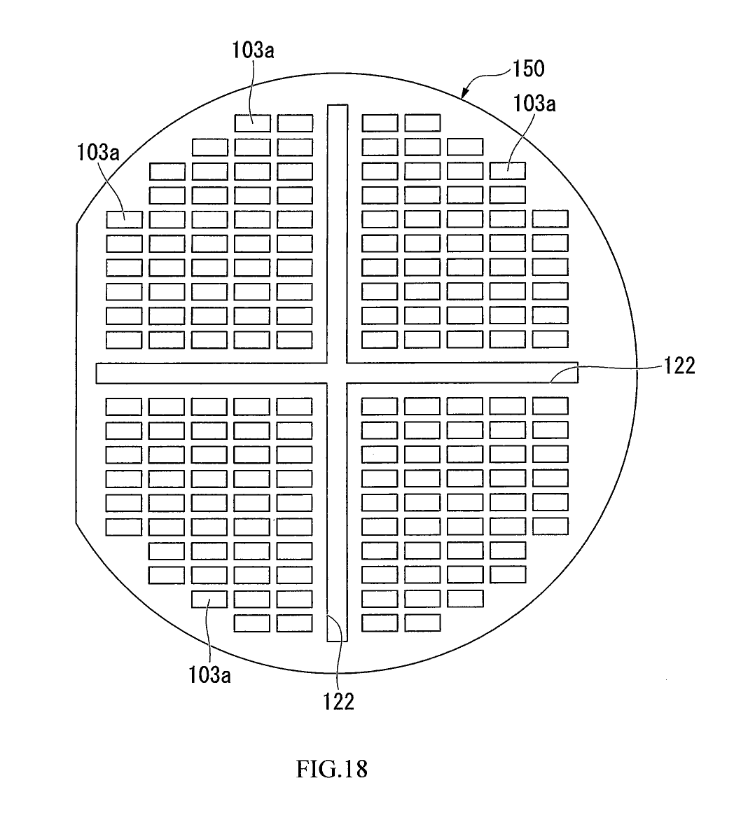

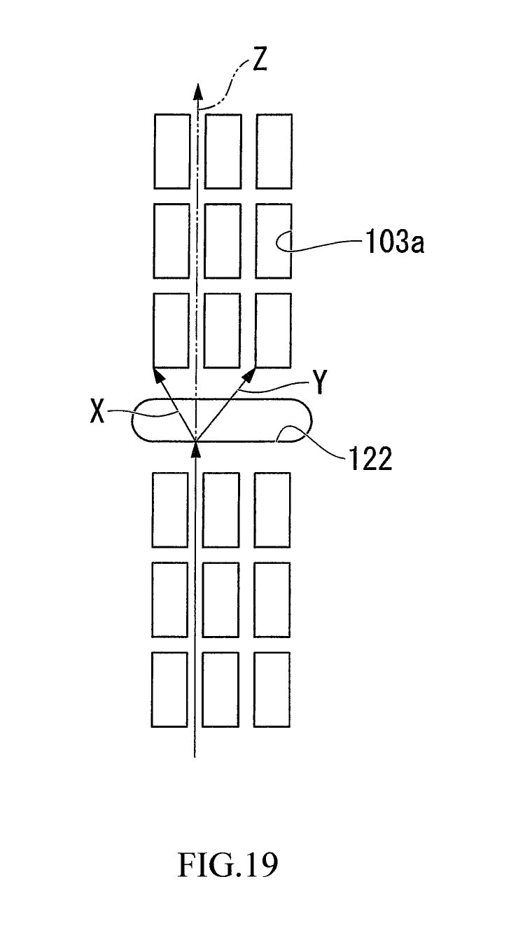

FIGS. 16 include diagrams showing the cutting step. FIG. 16A is a plan view of the wafer bonded unit, and FIG. 16B is a section view taken along line D-D.

As shown in FIGS. 16, after the fine adjustment of the frequency is finished, the wafer bonded unit 60 is cut (S90). Specifically, a UV tape is affixed to the face of the wafer for base substrate 40 of the wafer bonded unit 60 opposite to the bonding face. Next, laser light is applied from the side of the wafer for lid substrate 50 to form a scribe line in the surface portion of the face of the wafer for lid substrate 50 opposite to the bonding face.

Next, a cutting blade is put onto the surface of the UV tape toward the scribe line to split the wafer bonded unit 60 (breaking). The cutting blade has a blade longer than the diameter of the wafer bonded unit 60.

The cutting step (S90) of the present embodiment includes a separation step of separating the product regions 40c and 50c of the wafer bonded unit 60 into the non-forming region N1 and the recess portion forming region N2 and a singulation step of cutting the recess portion forming region N2 along the cutting lines M for singulation into a plurality of piezoelectric oscillators 1.

First, in the separation step, both sides in a width direction of each groove portion 22 extending along the imaginary straight line V1 are cut along a pair of cutting lines M1 in parallel with the imaginary straight line V1 with the groove portions 22 interposed between them such that the cutting is performed through the portion in which the groove portions 22 are not formed. In addition, both sides in a width direction of each groove portion 22 extending along the imaginary straight line V2 are cut along a pair of cutting lines M2 in parallel with the imaginary straight line V2 with the groove portions 22 interposed between them such that the cutting is performed through the portion in which the groove portions 22 are not formed. This results in the wafer bonded unit 60 cut in a cross shape. At this point, in the wafer bonded unit 60, the non-forming region N1 is divided into the regions of the central portions 40a and 50a in the diameter direction (non-forming region of the groove portions 22) and the forming region of each groove portion 22, and the recess portion forming region N2 is divided into four in a fan shape.

Then, the wafer bonded unit 60 is cut along the cutting lines M (see FIG. 15) to singulate the wafer bonded unit 60 for each cavity C in the recess portion forming region N2.

After the singulation step, UV is applied to the wafer bonded unit 60 to peel the UV tape. This can separate the wafer bonded unit 60 into the plurality of piezoelectric oscillators 1. Alternatively, the wafer bonded unit 60 may be cut with a different method such as dicing.

This can result in the manufacturing of a number of piezoelectric oscillators 1 of the surface-mounting type shown in FIG. 1 at a time in which the piezoelectric oscillating piece 4 is enclosed within the cavity C formed between the anodic-bonded base substrate 2 and lid substrate 3.

The step order may be changed such that the fine adjustment step (S80) is performed after the cutting step (S90) is performed for the singulation into each piezoelectric oscillator 1. However, the fine adjustment step (S80) can be performed first as described above to enable the fine adjustment of the whole wafer bonded unit 60, so that a number of piezoelectric oscillators 1 can be fine adjusted more efficiently. This is more preferable since the throughput can be improved.

Then, an internal electric characteristic test is performed (S 100). Specifically, the resonance frequency, the resonance resistance value, the drive level characteristics (dependency of the resonance frequency and the resonance resistance value on the exciting power) and the like of the piezoelectric oscillating piece 4 are measured and checked. In addition, the insulation resistance characteristic is also checked. Finally, the outer appearance test of the piezoelectric oscillator 1 is performed to check the dimensions, quality and the like finally. Thus, the manufacturing of the piezoelectric oscillator 1 is finished.

In this manner, the present embodiment is configured such that the groove portions 22 are formed in the non-forming region N1 of the wafer for lid substrate 50.

According to the structure, the groove portions 22 formed in the wafer for lid substrate 50 allow the out-gas emitted between the wafers 40 and 50 at the bonding step (S60) as described above to stay in the groove portions 22. As a result, the wafers 40 and 50 can be bonded with a small amount of out-gas remaining in the cavities C, so that the piezoelectric oscillator 1 can be manufactured at a high degree of vacuum in the cavity C. Since the series resonance resistance value (R1) of the piezoelectric oscillator 1 can be held low, the piezoelectric oscillating piece 4 can be oscillated at low power, thereby making it possible to manufacture the piezoelectric oscillator 1 with high energy efficiency.

Especially, in the present embodiment, the abovementioned groove portions 22 are formed individually along the imaginary straight lines V1 and V2 at the positions avoiding the central portion 50a in the diameter direction in the non-forming region N1.

According to the structure, both sides of the groove portions 22 are previously cut along the imaginary straight lines V1 and V2 (cutting lines M1 and M2) at the separation step of the cutting step (S90) and then the recess portion forming region N2 is cut along the cutting lines M at the singulation step, so that the cutting does not need to be performed across the groove portions 22. In other words, since the cutting is not performed across the non-bonding portion of the wafer 40 or 50 having low strength but performed only in the bonding portion of the wafers 40 and 50 having high strength, the wafer bonded unit 60 can be cut along the desired cutting line.

This can prevent the cutting from deviating from the desired cutting line to cause cracks, so that it is possible to increase the strength of the piezoelectric oscillator 1 and to prevent defective items in which the cavity C communicates with the outside. Thus, the yields can be improved.

In this manner, according to the present embodiment, the out-gas emitted between the wafers 40 and 50 during the bonding of the wafers 40 and 50 can be easily discharged to the outside, and the wafer bonded unit 60 can be cut favorably, thereby improving the yields.

In addition, in the present embodiment, the imaginary straight lines V1 and V2 are set in a cross shape on the wafer for lid substrate 50, and the recess portion 3a is formed such that the shorter-side direction thereof extends in parallel with the imaginary straight line V1 and the longer-side direction thereof extends in parallel with the imaginary straight line V2.

According to the structure, the groove portions 22 can be formed while suppressing an increase in space between the adjacent cavities C (recess portions 3a). The recess portion forming region N2 can be efficiently set on the wafer for lid substrate 50 to maintain the yields of the group of package products which can be formed from one wafer 50. As a result, even when the groove portions 22 are formed, the number of the piezoelectric oscillators 1 taken from one wafer 50 can be ensured.

In addition, the formation of the groove portions 22 at the positions avoiding the central portion 50a in the diameter direction along the imaginary straight lines V1 and V2 allows the separation of the non-forming region N1 (the forming region of the groove portions 22) from the recess portion forming region N2 with the small number of cuttings at the separation step to improve the manufacturing efficiency. Since the sizes (recess portion forming regions N2) of the cut wafers for lid substrate 50 can be uniform, the operation of the next step (for example, the singulation step) can be facilitated.

The technological scope of the present invention is not limited to the embodiment described above, and various changes can be made without departing from the spirit or scope of the present invention.

While the groove portions 22 are formed in the wafer for lid substrate 50 in the above embodiment, the groove portions 22 may be formed in the wafer for base substrate 40.

While the above embodiment has been described with the case in which the two imaginary straight lines V1 and V2 are formed in the cross shape, the number of imaginary straight lines may be three or more as long as they pass through the center of the wafer for lid substrate 50.

For the groove portions 22 formed along the same imaginary straight line, three or more groove portions 22 may be formed as long as the groove portions 22 are separately formed.

While the groove portions 22 are formed at the positions avoiding the central portion 50a in the diameter direction in the above embodiment, the avoiding position is not limited to the central portion 50a in the diameter direction but the design thereof may be changed as appropriate. For example, when the groove portion 22 is formed at the central portion 50a in the diameter direction on the one imaginary straight line V1 as shown in FIG. 17, the groove portion 22 may be formed to avoid the central portion 50a in the diameter direction on the other imaginary straight line V2.

In this case, at the separation step of the cutting step (S100), both sides of the pair of groove portions 22 (the groove portions 22 along the imaginary straight line V1) present at the central portion 50a in the diameter direction are first cut along the cutting lines M1, and then, both sides of the pair of groove portions 22 (the groove portions 22 along the imaginary straight line V2) not present at the central portion in the diameter direction are cut along the cutting lines M2 to cut out the groove portions 22.

At the bonding film forming step (S34) described above, the patterning may be performed not to form the bonding film 27 in the portion located on the outer side in the radial direction than the outer end of the groove portion 22 in the radial direction.

In this case, since the portion located between the outer end of the groove portion 22 in the radial direction and the outer circumference of the wafers 40 and 50 is not bonded between the wafers 40 and 50, the out-gas can be easily discharged through the small gap between them at the bonding step (S60).

The groove portion 22 may be opened from the outer circumference of the wafer for lid substrate 50. In this case, since the out-gas discharged into the groove portion 22 during the bonding is discharged to the outside through the groove portion 22, the out-gas can be discharged more reliably.

While the above embodiment has been described in the case in which the separated recess portion forming regions N2 after the separation step are transferred together to the singulation step, the present invention is not limited thereto, and each of the recess portion forming regions N2 may be cut individually at the singulation step.

While the piezoelectric oscillating piece 4 is bump-bonded in the embodiment described above, the present invention is not limited to the bump bonding. For example, the piezoelectric oscillating piece 4 may be bonded with a conductive adhesive. However, the bump bonding can separate the piezoelectric oscillating piece 4 from the base substrate 2 to ensure naturally the minimum oscillation gap necessary for the oscillation. The bump bonding is preferable in this respect.

In addition, while the embodiment described above shows the piezoelectric oscillator 1 as the package product, a device other than the piezoelectric oscillator 1 may be manufactured by putting an electronic part other than the piezoelectric oscillating piece within the package product.

In addition, the components in the embodiment described above can be replaced with well-known components as appropriate without departing from the spirit or scope of the present invention, and the abovementioned modifications may be combined as appropriate.

What is claimed is:

1. A wafer bonded unit, comprising:
a first wafer having a bonding surface and comprising a plurality of package products; and
a second wafer having a bonding surface bonded to the bonding surface of the first wafer, the second wafer comprising:
a plurality of forming regions, each comprising a plurality of cavities, wherein a position of each of the cavities corresponds to a position of one of the package products within the first wafer; and
a non-forming region comprising a first line region extending in a first direction that passes through a center of the second wafer and a second line region extending in a second direction that intersects with the first line region at the center of the second wafer such that the non-forming region separates each of the non-forming regions, wherein the non-forming region further comprises:
a first groove portion and a second groove portion, each extending in a direction parallel to the first direction within the first line region; and
a third groove portion and a fourth groove portion, each extending in a direction parallel to the first direction within the second line region.

2. The semiconductor wafer of claim 1, wherein the first line region and the second line region are substantially orthogonal to each other.

3. The semiconductor wafer of claim 1, wherein the first groove portion and the second groove portion each define a recess within the non-forming region.

4. The semiconductor wafer of claim 1, wherein the first groove portion and the second groove portion are not in contact with each other.

5. The semiconductor wafer of claim 4, wherein the first groove portion and the second groove portion are separated by a separation region within the non-forming region.

6. The semiconductor wafer of claim 5, wherein the separation region encompasses the region of the non-forming region where the first line region and the second line region intersect.

7. The semiconductor wafer of claim 4, wherein a portion of the third groove portion extends between the first groove portion and the second groove portion.

8. The semiconductor wafer of claim 1, wherein none of the first, second, third, or fourth groove portions are in contact with each other.

9. The semiconductor wafer of claim 1, wherein the first wafer and the second wafer each comprise a plate shape.

10. A method for forming a wafer bonded unit, comprising:
forming a second wafer having a bonding surface;
forming a first wafer having a bonding surface, the bonding surface having a plurality of forming regions separated by a non-forming region;
forming a plurality of groove portions within the non-forming region along one of a first line region or a second line region, wherein:
the first line region extends in a first direction that passes through a center of the second wafer and the second line region extending in a second direction that passes through the center of the second wafer, and
the plurality of groove portions are formed such that none of the plurality of groove portions are in contact with each other;
mounting a plurality of package products on the first wafer; and
bonding the bonding surface of the first wafer to the bonding surface of the second wafer.

11. The method of claim 10, further comprising forming a plurality of cavities on the bonding surface of the first wafer, wherein each of the plurality of cavities are formed in one of the plurality of forming regions.

12. The method of claim 10, wherein the first line region and the second line region are substantially orthogonal to each other.

13. The method of claim 10, wherein each of the plurality of groove portions is formed to define a recess within the non-forming region.

14. The method of claim 10, wherein forming the plurality of groove portions comprises:
forming a first groove portion and a second groove portion within the first line region; and
forming a third grove portion and a fourth groove portion within the second line region.

15. The method of claim 14, wherein the first groove portion and the second groove portion are formed such that each is not in contact with the other.

16. The method of claim 15, wherein the first groove portion and the second groove portion are separated by a separation region within the non-forming region.

17. The method of claim 16, wherein the separation region encompasses the region of the non-forming region where the first line region and the second line region intersect.

18. The method of claim 15, wherein the third groove portion is formed such that a portion of the third groove portion extends between the first groove portion and the second groove portion.

19. The method of claim 10, wherein the plurality of groove portions are formed such that none of the groove portions are in contact with another groove portion.

20. The method of claim 10, wherein each of the first wafer and the second wafer are formed into a plate shape.

21. The method of claim 10, wherein during bonding the plurality of grove portions guide out-gas emitted between the wafers.

22. The method of claim 10, wherein bonding comprises anodic bonding the bonding surfaces of the first and second wafer together.
